(19) United States
(12) Patent Application Publication
(10) Pub. No.: US 2022/0271175 A1
(43) Pub. Date: Aug. 25, 2022

(54) SOLAR CELL-ATTACHED ELECTRONIC EQUIPMENT

(71) Applicant: SHARP KABUSHIKI KAISHA, Sakai City, Osaka (JP)

(72) Inventor: SATOSHI SHIMIZU, Sakai City, Osaka (JP)

(21) Appl. No.: 17/628,151

(22) PCT Filed: Jul. 17, 2020
(86) PCT No.: PCT/JP2020/027866

§ 371 Date: Jan. 18, 2022

(30) Foreign Application Priority Data
Jul. 29, 2019 (JP) 2019-138788

(51) Int. Cl. H01L 31/02; H02S 40/34; H01L 31/042

(52) U.S. Cl. CPC H01L 31/02008; H02S 40/34; H01L 31/042

(57) ABSTRACT

Provided is solar cell-attached electronic equipment (100) including: a board (30) including a wire and a land; a conductive cushion material (31a, 31b) disposed on the board (30); and a solar cell (20) disposed to face the board (30). The solar cell (20) including an electrode (21a, 21b) disposed to face the land. The land and the electrode (21a, 21b) are electrically connected together through the conductive cushion material (31a, 31b).

### TECHNICAL FIELD

The present application claims priority from Japanese Application JP2019-138788 filed on Jul. 29, 2019, the content of which is hereby incorporated by reference into this application.

The present disclosure relates to a technique of solar cell-attached electronic equipment provided with a solar cell.

### TECHNICAL FIELD

There are conventionally known pieces of electronic equipment provided with solar cells and communications antennas. For example, Japanese Unexamined Patent Application Publication No. 2006-344616 (Patent Document 1) discloses a method for mounting a glass substrate of a solar cell. Patent Document 1 discloses that an electrode for a glass substrate of a solar cell and an electrode; namely, a land, for a printed wiring board are electrically connected together through a conductive paste, and, between a protective film of the solar cell and the printed wiring board, an insulating adhesive is applied to attach the solar cell and the printed wiring board together to render the solar cell and the printed wiring board mechanically strong. This method makes it possible to produce a module of reliable solar cells at low production costs, or products and kits using such solar cells.

Japanese Unexamined Patent Application Publication No. H08-306950 (Patent Document 2) discloses a piece of electronic equipment including a solar cell and a solar cell terminal. In Patent Document 2, a remote controller includes: an operating element; a transmitter; a dry cell; a circuit board on which a predetermined electronic component is mounted; a single-piece solar cell module having an electrode; and an attachment having a recess to which the solar cell module can be attached. The solar cell module is connected to, and provides power to, a circuit processor of the remote controller through the solar cell terminal.

### CITATION LIST

### Patent Literature

Patent Document 1: Japanese Unexamined Patent Application Publication No. 2006-344616

Patent Document 2: Japanese Unexamined Patent Application Publication No. H08-306950

### SUMMARY OF INVENTION

### Technical Problem

The present disclosure is intended to provide solar cell-attached electronic equipment whose solar cell is easily replaceable.

### Solution to Problem

An aspect of the present disclosure provides solar cell-attached electronic equipment including: a board including a wire and a land; a conductive cushion material disposed on the board; and a solar cell disposed to face the board. The solar cell includes an electrode disposed to face the land. The land and the electrode are electrically connected together through the conductive cushion material.

### Advantageous Effects of Invention

As can be seen, the present disclosure can provide solar cell-attached electronic equipment whose solar cell is easily replaceable.

### BRIEF DESCRIPTION OF DRAWINGS

FIG. 1 is a front elevation view of entire solar cell-attached electronic equipment 100 according to a first embodiment.

FIG. 2 is an image illustrating a use condition of the solar cell-attached electronic equipment 100 according to the first embodiment.

FIG. 3 is a front perspective view of the solar cell-attached electronic equipment 100 during assembly according to the first embodiment.

FIG. 4 is an image of a dye-sensitized solar cell 20, a board 30, and conductive cushion materials 31a and 31b according to the first embodiment.

FIG. 5 is a cross-sectional view of a cushion material 11, a positive electrode 21a, the board 30, and the conductive cushion material 31a according to the first embodiment.

FIG. 6 is a cross-sectional view of the cushion material 11, a negative electrode 21b, the board 30, and the conductive cushion material 31b according to the first embodiment.

FIG. 7 is an image of the solar cell 20, the board 30, and the conductive cushion material 31a according to the first embodiment.

FIG. 8 shows images of the conductive cushion material 31a before and during compression according to the first embodiment.

FIG. 9 is a cross-sectional image of a configuration of the conductive cushion materials 31a and 31b according to the first embodiment.

FIG. 10 is cross-sectional view of surroundings of the positive electrode 21a and the conductive cushion material 31a before a conductive cushion material 31 is compressed.

FIG. 11 is a cross-sectional view of surroundings of the positive electrode 21a and the conductive cushion material 31a while the conductive cushion material 31 is compressed.

FIG. 12 is a cross-sectional view of surroundings of the negative electrode 21b and the conductive cushion material 31b while the conductive cushion material 31 is compressed.

FIG. 13 is a circuit diagram illustrating the board 30 according to the first embodiment.

FIG. 14 shows graphs illustrating variation in a voltage of a charge element according to the first embodiment.

FIG. 15 shows rear perspective views of the solar cell-attached electronic equipment 100 during assembly according to the first embodiment.

FIG. 16 is a front perspective view of a configuration of the board 30 according to the first embodiment.

FIG. 17 is a cross-sectional view of an arrangement of the board 30, the dye-sensitized solar cell 20, an inspection pad 51, and a charge element 52 according to the first embodiment.

FIG. 18 is a cross-sectional view of an interior of a cover 10 according to the first embodiment.

FIG. 19 is a cross-sectional view of an outer periphery of the cover 10 according to the first embodiment.

FIG. 20 is an image illustrating how the solar cell-attached electronic equipment 100 according to the first embodiment goes down when the solar cell-attached electronic equipment 100 falls.

FIG. 21 is a rear view of the solar cell-attached electronic equipment 100 while a rear cover 40 according to the first embodiment 40 is attached.

FIG. 22 is a cross-sectional view of an arrangement of the board 30, the dye-sensitized solar cell 20, the inspection pad 51, and the charge element 52 according to a second embodiment.

FIG. 23 is a cross-sectional view of an arrangement of the board 30, the dye-sensitized solar cell 20, the inspection pad 51, and the charge element 52 according to the second embodiment.

FIG. 24 is a rear view of the solar cell-attached electronic equipment 100 according to a third embodiment while the rear cover 40 is not attached.

### DESCRIPTION OF EMBODIMENTS

Embodiments of the present disclosure will be described below, with reference to the drawings. In the description below, identical components have the same reference signs. These components have the same names and functions. Such components will not be repeatedly elaborated upon.

### First Embodiment

Overall Configuration of Solar Cell-Attached Electronic Equipment 100

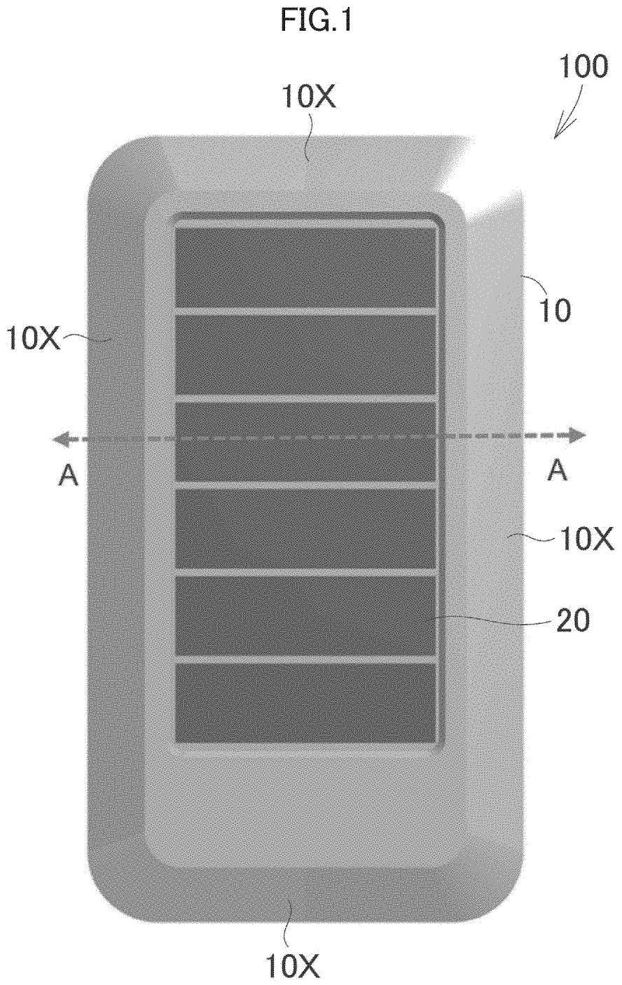

Described first is an overall configuration of solar cell-attached electronic equipment 100 according to this embodiment. With reference to FIG. 1, the solar cell-attached electronic equipment 100 according to this embodiment is a vertically-oriented substantial rectangle when observed from the front.

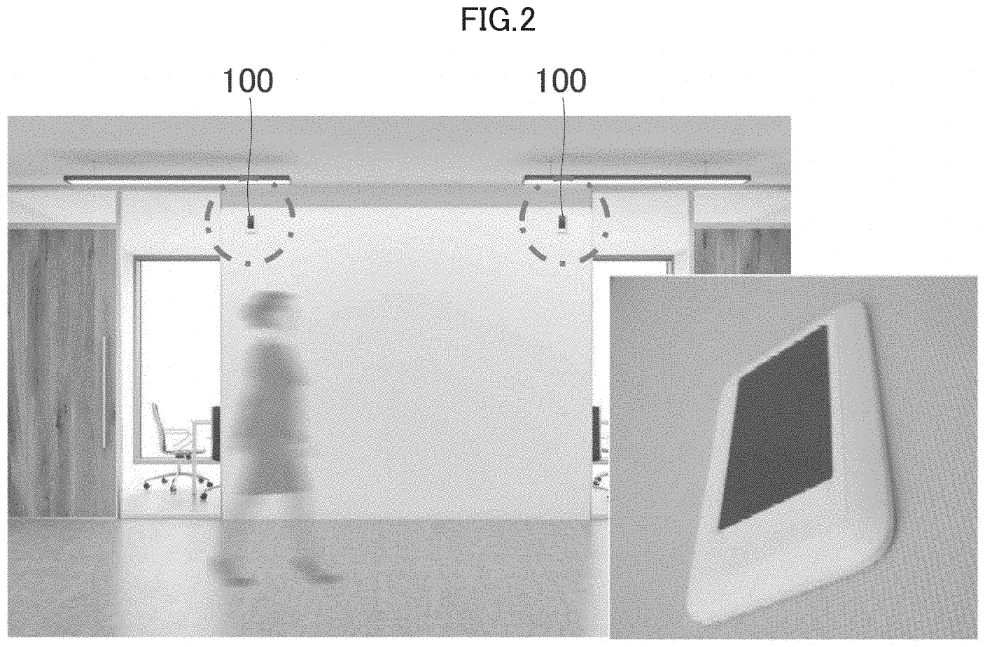

As illustrated in FIG. 2, the solar cell-attached electronic equipment 100 according to this embodiment is attached to, for example, a wall and a ceiling when used. Preferably, multiple pieces of the solar cell-attached electronic equipment 100 are disposed in, for example, a building or an underground shopping complex. Each piece of the solar cell-attached electronic equipment 100 emits a specific signal. A personal digital assistance such as a smart phone held by a pedestrian receives the specific signal, such that the personal digital assistance can identify a specific current location of itself, and obtain other information.

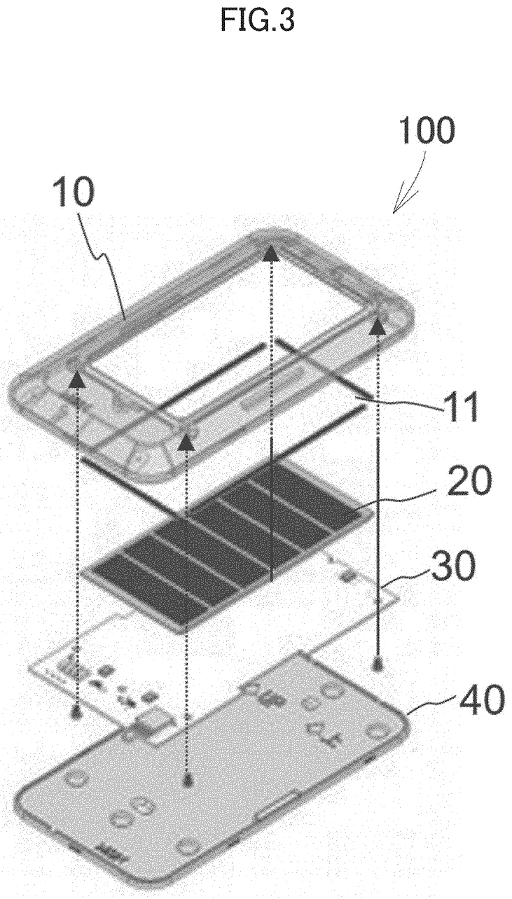

As illustrated in FIG. 3, the solar cell-attached electronic equipment 100 according to this embodiment mainly includes: a front cover 10; a cushion material 11; a dye-sensitized solar cell 20 (hereinafter also referred to as a DSC); a printed wiring circuit board 30; and a rear cover 40.

The front cover 10 includes an opening formed for exposing a generator of the dye-sensitized solar cell 20. The front cover 10 is, for example, a molded resin product.

The cushion material 11 is elastic and capable of absorbing various impacts.

The dye-sensitized solar cell 20 can also be used in an indoor environment. The dye-sensitized solar cell 20 can easily generate electricity even with light from a fluorescent lamp. Furthermore, in another embodiment, the dye-sensitized solar cell 20 may be replaced with another solar cell such as an amorphous silicon solar cell.

The rear cover 40 is made of such a material as resin. The rear cover 40 is fastened to the front cover 10 with screws or snap-fits. The front cover 10 and the rear cover 40 constitute a casing to house the dye-sensitized solar cell 20 and the printed wiring circuit board 30.

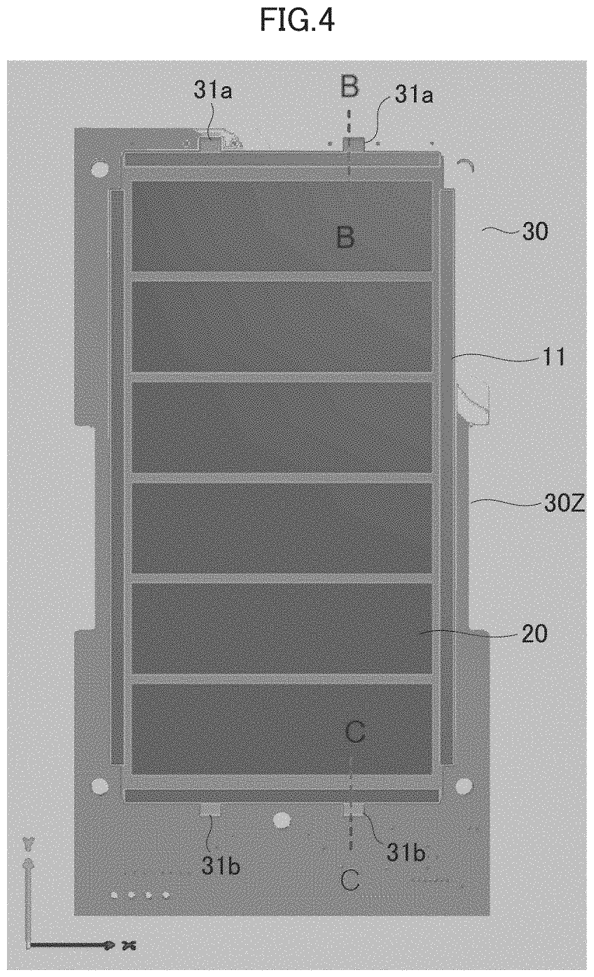

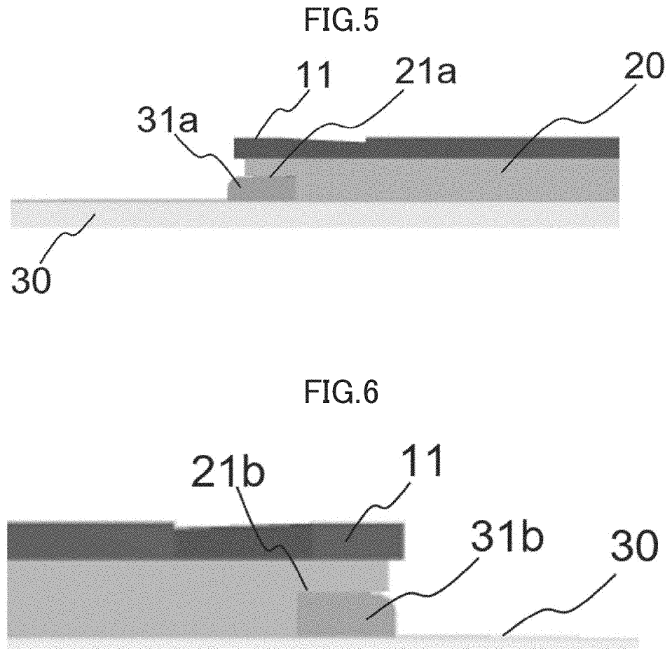

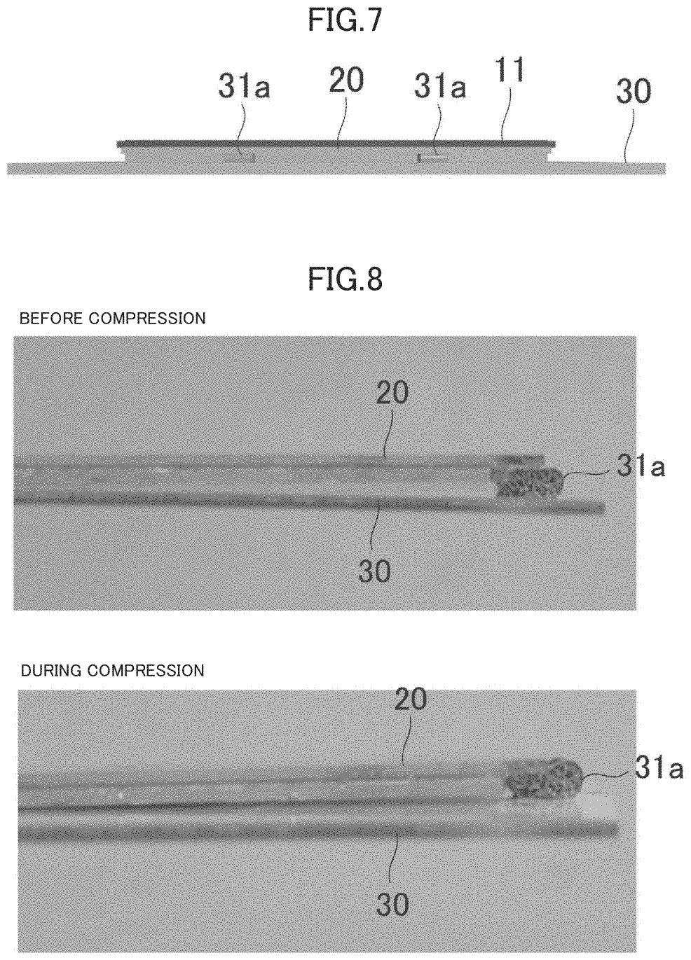

Particularly, in the solar cell-attached electronic equipment 100 according to this embodiment, the dye-sensitized solar cell 20 as illustrated in FIGS. 4 to 8 is electrically connected to the printed wiring circuit board 30 through the conductive cushion materials 31a and 31b.

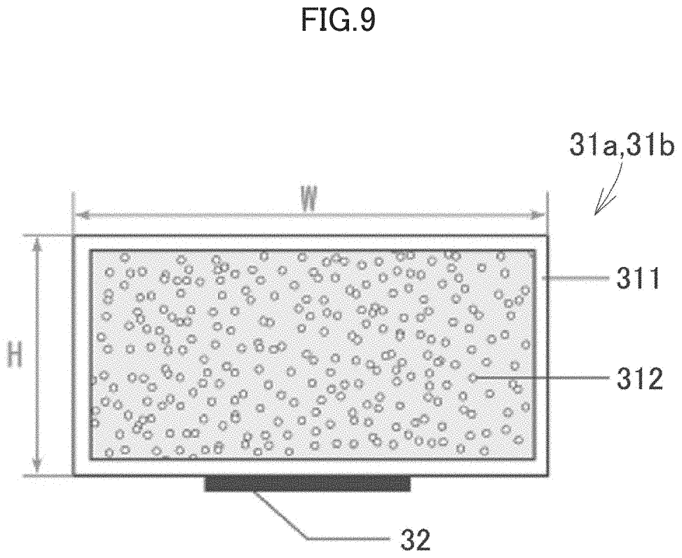

As illustrated in FIG. 9, the conductive cushion materials 31a and 31b in this embodiment each include: an elastic material 312 such as polyurethane; and a conductive cloth 311 wrapping the elastic material 312. Other than the elastic material 312, the conductive cushion materials 31a and 31b may contain powder of a highly conductive metal such as Cu. Moreover, the conductive cushion materials 31a and 31b may be made of an elastic metal. Instead of the elastic material 312, the conductive cushion materials 31a and 31b may be made of the conductive cloth 311 and a flexible metal stacked on top of another. The conductive cushion materials 31a and 31b shall not be limited to the above configurations, as long as each of the conductive cushion materials 31a and 31b may readily conduct electricity between an upper portion and a lower portion thereof and may be transformable on the whole.

As illustrated in FIGS. 4 to 12, the conductive cushion materials 31a and 31b have bottom faces respectively fastened to lands 32a and 32b connected to wiring formed on the printed wiring circuit board 30. The conductive cushion materials 31a and 31b also have top faces respectively connected to a positive electrode 21a and a negative electrode 21b of the dye-sensitized solar cell 20. More specifically, the bottom face of the conductive cushion materials 31a and 31b are stuck to the lands 32a and 32b with a double-sided adhesive tape 32 that is conductive, and are electrically and physically connected to the printed wiring circuit board 30. Furthermore, the conductive cushion materials 31a and 31b may respectively be soldered to the lands 32a and 32b. Meanwhile, the top faces of the conductive cushion materials 31a and 31b may respectively and electrically be connected to, but not stuck to, the positive electrode 21a and the negative electrode 21b of the dye-sensitized solar cell 20. The conductive cushion materials 31a and 31b and an outer peripheral edge of the dye-sensitized solar cell 20 are sandwiched between the cushion material 11 attached to the front cover 10 and the printed wiring circuit board 30. The above features make it possible to ensure electrical connection between the dye-sensitized solar cell 20 and the lands 32a and 32b as long as the positive electrode 21a (a first electrode) and the negative electrode 21b (a second electrode) are respectively in contact with the conductive cushion materials 31a and 31b even if the dye-sensitized solar cell 20 are displaced from its original position.

In this embodiment, preferably, the conductive cushion materials 31a and 31b are provided to longitudinally opposing ends of the dye-sensitized solar cell 20. Preferably, two or more conductive cushion materials 31a and 31b are provided along the opposing ends. In other words, at the positive electrode 21a of the dye-sensitized solar cell 20, two conductive cushion materials 31a are pressed between the outer periphery edge of the dye-sensitized solar cell 20 and a land of the board 30. At the negative electrode 21b of the dye-sensitized solar cell 20, two conductive cushion materials 31b are pressed between the outer periphery edge of the dye-sensitized solar cell 20 and a land of the board 30.

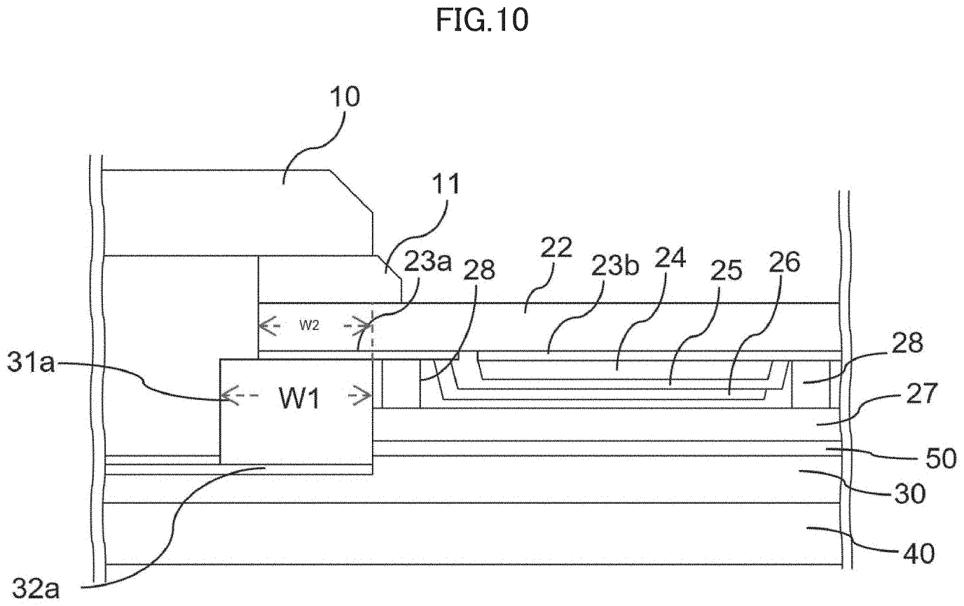

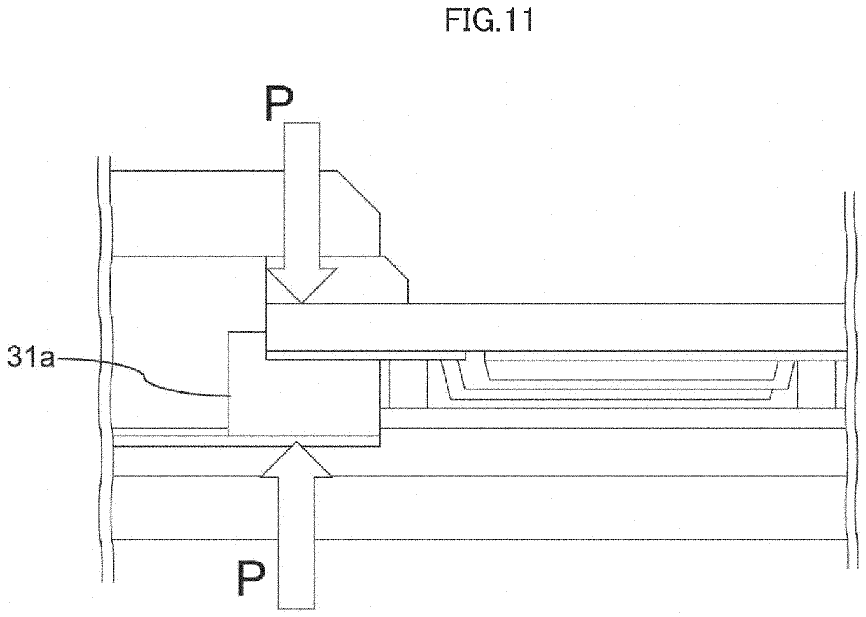

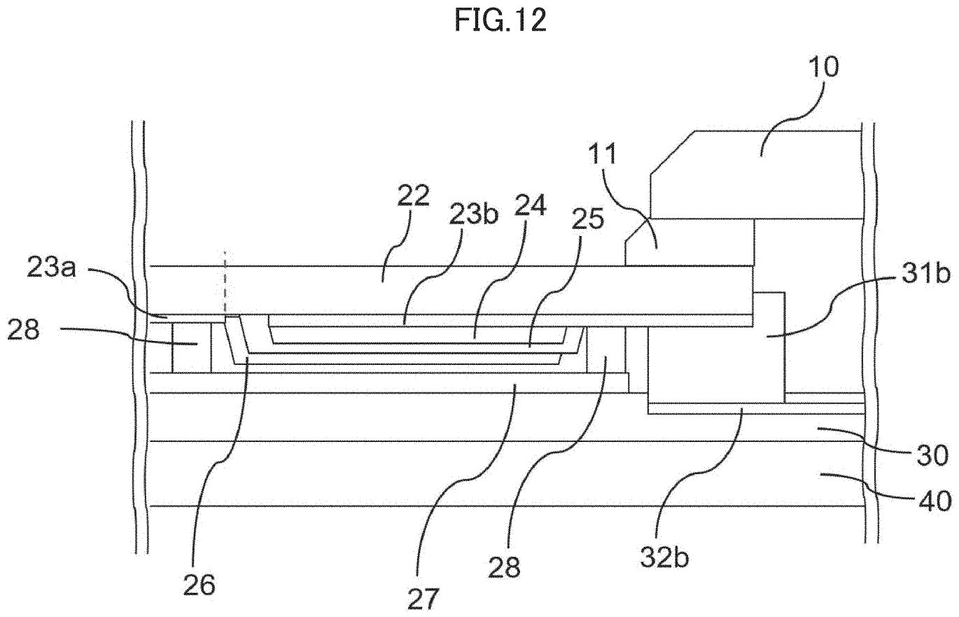

With reference to FIGS. 10 to 12, specified below is a configuration of the dye-sensitized solar cell 20 according to this embodiment. FIG. 10 is a cross-sectional view of surroundings of the positive electrode 21a and the conductive cushion material 31a before the conductive cushion material 31a is compressed. FIG. 11 is a cross-sectional view of surroundings of the positive electrode 21a and the conductive cushion material 31a while the conductive cushion material 31a is compressed. FIG. 12 is a cross-sectional view of surroundings of the negative electrode 21b and the conductive cushion material 31b while the conductive cushion material 31b is compressed.

The dye-sensitized solar cell 20 disclosed in this embodiment includes six unit cells connected in series. Each of the unit cells includes: a first light-transparent substrate 22 having a light receiving face; light-transparent conductive layers 23a and 23b provided on a face, of the first light-transparent substrate 22, across from the light receiving face; a porous semiconductor layer 24 provided on the light-transparent conductive layer 23b; a porous insulating layer 25 provided on the porous semiconductor layer 24; a counter electrode conductive layer 26 provided on the porous insulating layer; a counter substrate 27 facing the first light-transparent substrate; and a sealing layer 28. The unit cells share the first light-transparent substrate 22 and the counter substrate 27. The porous semiconductor layer 24 contains an electrolyte and carries dye. The porous insulating layer 25 contains an electrolyte including a redox species. The sealing layer 28 functions to isolate the electrolyte not to move among the unit cells.

The light-transparent conductive layer 23a electrically connects to the counter electrode conductive layer 26 of a neighboring unit cell, and acts as a positive electrode of each unit cell. The light-transparent conductive layer 23a included in a unit cell and positioned closest to the positive electrode 21a of the dye-sensitized solar cell 20 corresponds to the positive electrode 21a of the dye-sensitized solar cell 20. The light-transparent conductive layer 23a is disposed across from the conductive cushion material 31a out of the sealing layer 28. The light-transparent conductive layer 23b corresponds to a negative electrode of each unit cell. The light-transparent conductive layer 23b included in a unit cell and positioned closest to the negative electrode 21b of the dye-sensitized solar cell 20 corresponds to the negative electrode 21b of the dye-sensitized solar cell 20. The light-transparent conductive layer 23b is disposed across from the conductive cushion material 31b out of the sealing layer 28. As can be seen, each of the longitudinal opposing ends of the first light-transparent substrate 22 is provided with one of the positive electrode 21a and the negative electrode 21b.

Note that a space 50 is created between the counter substrate 27 and the printed wiring circuit board 30 before a pressure P is applied.

The front cover 10 and the printed wiring circuit board 30 are fastened together with, for example, screws, to sandwich an edge of the dye-sensitized solar cell 20; that is, edges of the first light-transparent substrate 22 and the light-transparent conductive layer 23a, and the conductive cushion materials 31a and 31b. Here, as illustrated in FIGS. 11 and 12, the sandwiching pressure P transforms the conductive cushion material 31a.

With reference to FIG. 10, a width W1 of the conductive cushion material 31a before the transformation is preferably greater than an electrode width W2 (approximately 2 mm) corresponding to the light-transparent conductive layer 23a. The conductive cushion material 31a preferably lies 0.5 mm (W1-W2) or more off an end of the light-transparent conductive layer 23a acting as an electrode. When the board 30 and the dye-sensitized solar cell 20 vertically press the conductive cushion materials 31a and 31b lying off as illustrated in FIG. 11, outer ends of the conductive cushion materials 31a and 31b are raised toward the cover 10. As a result, the ends of the conductive cushion materials 31a and 31b keep the dye-sensitized solar cell 20 from being displaced. Such a feature makes it possible to hold the solar cells more stably.

A detailed configuration of the dye-sensitized solar cell 20 is disclosed in, for example, a booklet of WO2010/044445, and will not be repeatedly elaborated upon here.

Thanks to the configuration of the solar cell-attached electronic equipment 100 according to this embodiment, the dye-sensitized solar cell 20 and the printed wiring circuit board 30 can electrically connect to each other without sticking together. That is, when the front cover 10 is attached to the print wiring circuit board 30, the dye-sensitized solar cell 20 can be electrically connected to the printed wiring circuit board 30. In other words, such a feature can improve reliability of electrical connection between the dye-sensitized solar cell 20 and the printed wiring circuit board 30. Moreover, the front cover 10 is removed, and the dye-sensitized solar cell 20 with malfunction can be easily replaced with another one.

In particular, because the conductive cushion materials 31a and 31b are elastic, protruding widths of the first light-transparent substrate 22 and the counter substrate 27 are spontaneously adjusted and an effect of difference in level due to the counter substrate 27 is eliminated. Such features can facilitate electrical connection between the printed wiring circuit board 30 and an electrode of the dye-sensitized solar cell 20.

Furthermore, thanks to the cushioning property of the conductive cushion materials 31a and 31b, the printed wiring circuit board 30 and the dye-sensitized solar cell 20 can be electrically connected together more reliably, regardless of variation in glass thickness of the printed wiring circuit board 30 and the dye-sensitized solar cell 20.

Moreover, such techniques as A. providing a light reflector between the printed wiring circuit board 30 and the dye-sensitized solar cell 20, B. whitening a surface of the printed wiring circuit board 30, and C. using a reflective substrate to serve as the counter substrate can further improve efficiency in power generation.

In addition, while the conductive cushion materials 31a and 31b lie off the light-transparent conductive layer 23a, the dye-sensitized solar cell 20 is placed on the conductive cushion materials 31a and 31b, and the pressure P is applied to secure the dye-sensitized solar cell 20. Hence, as illustrated in FIGS. 8 and 11, the conductive cushion material 31a transforms. Here, the conductive cushion materials 31a and 31b per se hold a power generating element physically softly, making it possible to provide a more stable structure.

Inspection Mechanism of Solar Cell-Attached Electronic Equipment 100

Described next is an inspection mechanism of the solar cell-attached electronic equipment 100 according to this embodiment. In measuring a lower limit operating luminance of a photovoltaic element of the dye-sensitized solar cell 20, the photovoltaic element might temporality operate at, for example, an inspection step even under a luminance environment below the original lower limit operating luminance. Hence, it is difficult to accurately guarantee the lower limit operating luminance.

More specifically, in a case where power generated by a solar cell is used to operate a semiconductor load (e.g. an appliance using a microcomputer and a communications module for transmission of a beacon), if the charge element and the load are directly connected together, an inrush current is generated, when the load is activated, as soon as a charge voltage exceeds the lower limit operating voltage of the load. Hence, the charge voltage drops. As a result, the charge voltage falls below the lower limit operating voltage of the load, and the load stops. Hence, the load cannot be activated.

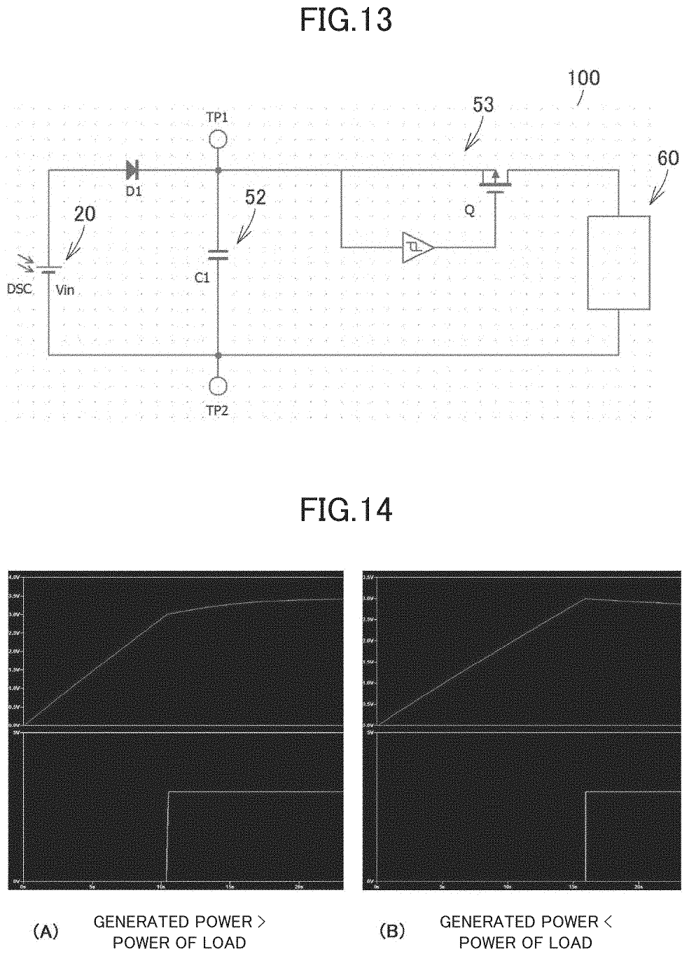

Thus, it is effective for the solar cell-attached electronic equipment 100 according to, for example, this embodiment to include a hysteresis switch 53 as illustrated in FIG. 13. The hysteresis switch 53 turns ON when the charge voltage exceeds an ON voltage, and turns OFF when the charge voltage falls below an OFF voltage. Because the ON voltage is set higher than the OFF voltage, the hysteresis switch 53 does not turn ON unless the charge voltage does not reach the ON voltage even if the charge voltage exceeds the OFF voltage when the hysteresis switch 53 is OFF. Moreover, the hysteresis switch 53 does not turn OFF even if the charge voltage falls below the ON voltage when the hysteresis switch 53 is ON. The hysteresis switch 53 turns OFF when the charge voltage falls below the OFF voltage.

As to the solar cell-attached electronic equipment 100 according to this embodiment, the power generated by the dye-sensitized solar cell 20 is stored in a charge element 52 such as a capacitor. When the charge voltage exceeds the ON voltage, the hysteresis switch 53 turns ON to supply the power to a load such as a communications module 60.

Here, if the generated power exceeds the power of the load, as illustrated in FIG. 14 (A), the charge voltage rises or remains constant, and the communications module 60 is continuously supplied with the power. If the generated power falls below the power of the load, as illustrated in FIG. 14 (B), the charge voltage is higher than, or equal to, the OFF voltage at first, and a load such as the communication module 60 is supplied with the power. However, the charge power gradually decreases. When the charge voltage falls below the OFF voltage, the hysteresis switch 53 turns OFF and the supply of the power to the communications module 60 stops.

Hence, even if the generated power falls below the power of the load, the load inevitably operates temporarily. When the operation is confirmed at a certain luminance, it is difficult to determine whether the load can continue operating at the luminance.

Thus, the solar cell-attached electronic equipment 100 according to this embodiment measures the charge voltage when the operation is confirmed, so that the determination is made as to whether the load continues operating at the luminance. Specifically, a light receiving face of the dye-sensitized solar cell 20 is irradiated with light at a certain luminance, and a charge voltage obtained as a result is observed. If the charge voltage increases with the elapse of time, and if the charge voltage is stable at a predetermined value or higher, it can be determined that the operation at the luminance is guaranteed.

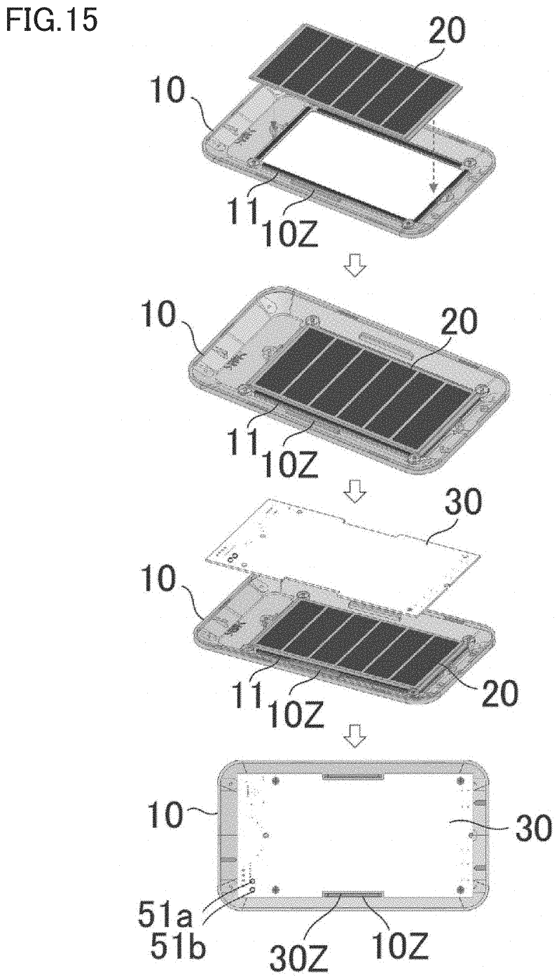

Specified below are an assembly step and an inspection step of the solar cell-attached electronic equipment 100 according to this embodiment. As illustrated in FIG. 15, the dye-sensitized solar cell 20 and the printed wiring circuit board 30 are stacked in the stated order on the cover 10 having an opening for the light receiving face of the dye-sensitized solar cell 20. More specifically, the dye-sensitized solar cell 20 is disposed to the cover 10 through the cushion material 11. To the dye-sensitized solar cell 20, the printed wiring circuit board 30 is disposed. The printed wiring circuit board 30 is provided with the conductive cushion materials 31a and 31b.

With the printed wiring circuit board 30 disposed to the dye-sensitized solar cell 20, the cover 10 and the printed wiring circuit board 30 are fastened together with screws. Hence, the lands 32a and 32b of the printed wiring circuit board 30, the conductive cushion materials 31a and 31b, the outer peripheral edge of the dye-sensitized solar cell 20, and the cushion material 11 are pressed against one another, and sandwiched between the cover 10 and the print wiring circuit board 30.

Here, in this embodiment, inspection pads 51a and 51b are exposed on a face, of the printed wiring circuit board 30, across from another face, of the printed wiring circuit board 30, connected to the dye-sensitized solar cell 20.

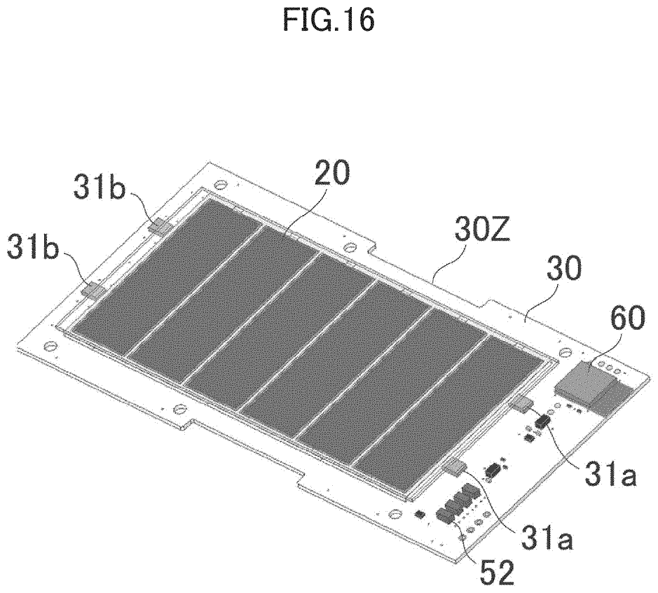

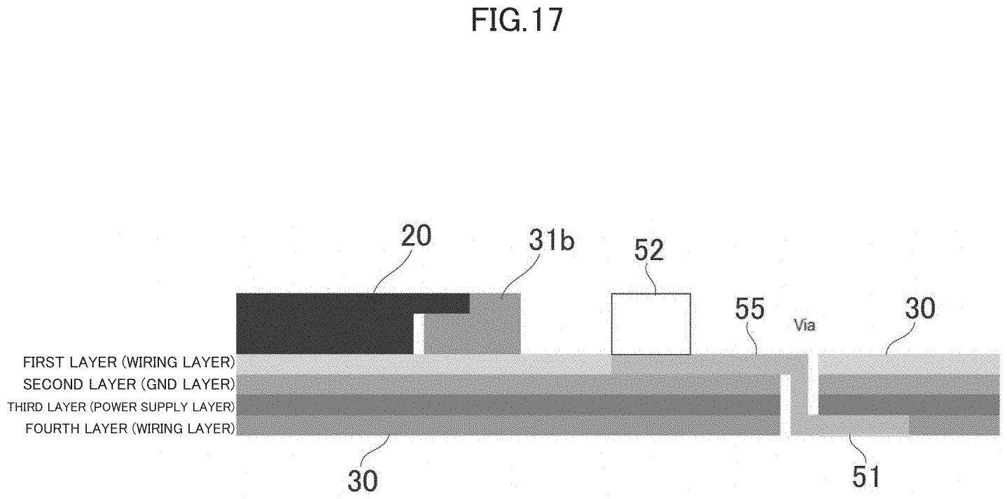

More specifically, as illustrated in FIGS. 16 and 17, the dye-sensitized solar cell 20 is attached to the center toward an end of a face of the printed wiring circuit board 30. In a space on the same face of the printed wiring circuit board 30 toward another end, electric components such as the communications module 60, the charge element 52, and various wires are arranged. In this embodiment, the inspection pads 51a and 51b are provided on the printed wiring circuit board 30, across from the dye-sensitized solar cell 20 and the charge element 52. More specifically, the charge element 52 includes a plurality of charge elements 52 connected in parallel. A wire 55 is routed from the positive ends of the charge elements 52 to the first inspection pad 51a, and from the negative ends of the charge elements 52 to the second inspection pad 51b.

Thanks to such features, while the dye-sensitized solar cell 20 and the printed wiring circuit board 30 are attached to the cover 10, an inspection worker can determine whether the solar cell-attached electronic equipment 100 is capable of generating sufficient power, or the dye-sensitized solar cell 20 and the printed wiring circuit board 30 are attached in a correct position and a correct orientation with respect to the cover 10.

Specifically, if the power generated by the dye-sensitized solar cell 20 is greater than the power of a load such as the communications module 60, the voltage between the inspection pads 51a and 51b increases immediately after the load turns ON. Meanwhile, as illustrated in FIG. 14 (B), if the power generated by the dye-sensitized solar cell 20 is smaller than the power of a load such as the communications module 60, the voltage between the inspection pads 51a and 51b starts to decrease immediately after the load turns ON. Before shipment of the solar cell-attached electronic equipment 100, the inspection worker can measure the voltage between the inspection pads 51a and 51b while the dye-sensitized solar cell 20 and the printed wiring circuit board 30 are attached as they are. That is, the inspection worker can determine, without effects of the cover and the casing, whether the dye-sensitized solar cell 20 can supply sufficient power to a load at a predetermined luminance.

Exterior of Solar Cell-Attached Electronic Equipment 100

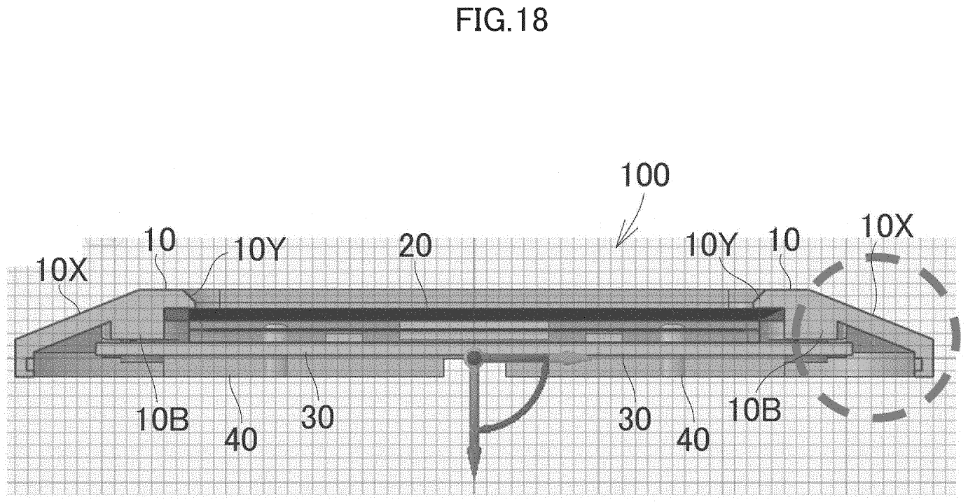

Described next is an exterior of the solar cell-attached electronic equipment 100 according to this embodiment. As illustrated in FIGS. 1 and 18, the front cover 10 of the solar cell-attached electronic equipment 100 is shaped into a substantial rectangular when observed from the front.

The front cover 10 includes an opening 10Y formed for the light-receiving face of the dye-sensitized solar cell 20. In this embodiment, the dye-sensitized solar cell 20 is attached to the center toward an end of a face of the printed wiring circuit board 30. In a space on the same face of the printed wiring circuit board 30 toward another end, electric components such as the communications module 60, the charge element 52, wires, and the lands 32a and 32b are arranged. The front cover 10 also covers the space in which the electric components at the other end are arranged.

In particular, according to this embodiment, the front cover 10 includes an outer edge 10X tapered. In other words, the front cover 10 has four sides inclined in cross-section. In still other words, each of the four sides of the front cover 10 is formed lower; that is, thinner, toward the outer peripheral end.

In still other words, the front cover 10 is shaped into a trapezoid in horizontal cross-section as illustrated in FIG. 18, and in not-shown vertical cross-section.

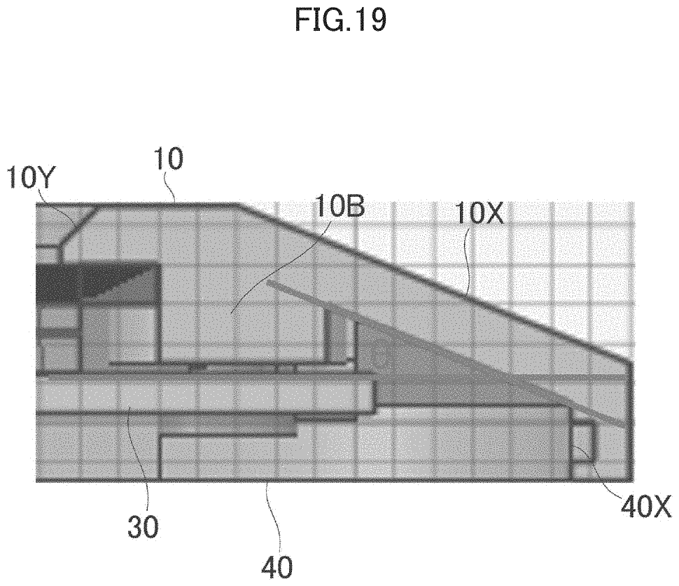

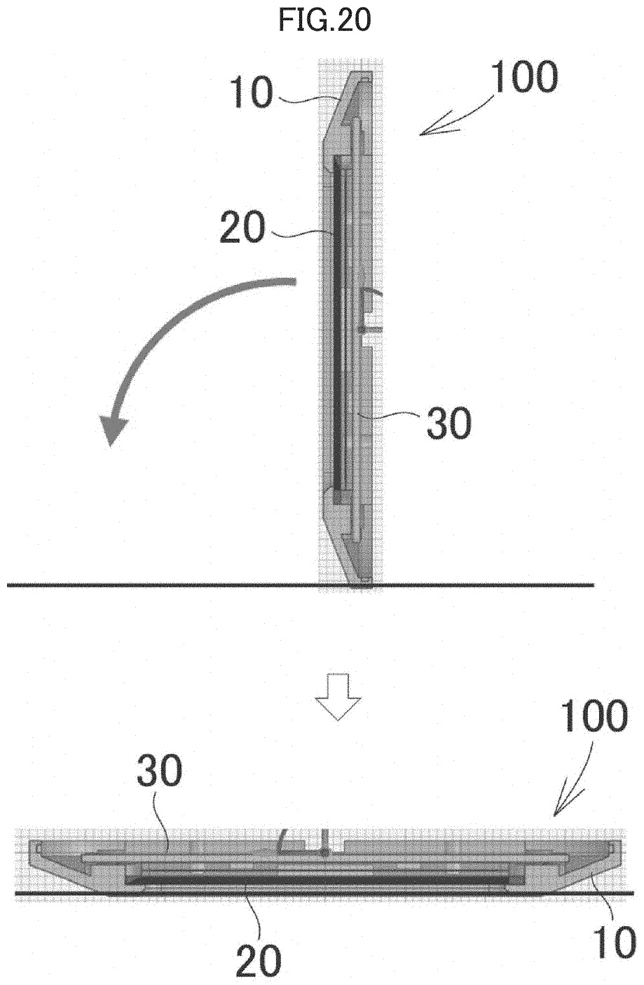

More specifically, as illustrated in FIG. 19, the front cover 10 has an end at an inclination θ ranging from 100 to 40°.

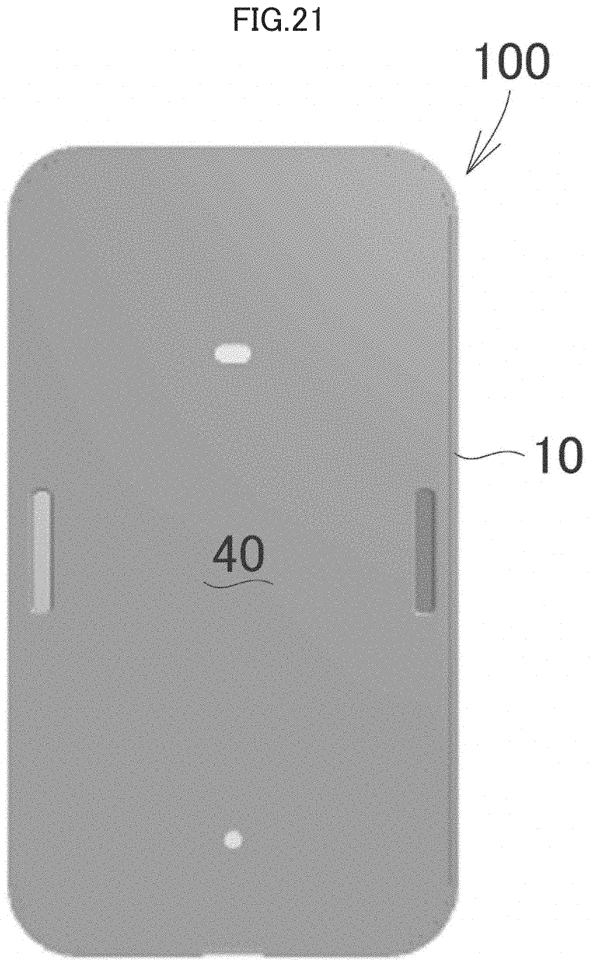

Hence, as illustrated in FIG. 20, even if the solar cell-attached electronic equipment 100 falls from, for example, a wall onto the floor, the solar cell-attached electronic equipment 100 is likely to go down with the light receiving face of the dye-sensitized solar cell 20 facing downwards. Such a feature can reduce the risk that, later on, the light receiving face of the dye-sensitized solar cell 20 might be stepped on with a shoe and have a scratch.

Moreover, the dye-sensitized solar cell 20 is less likely to receive light, and, immediately after going down, the power generating capacity of the dye-sensitized solar cell 20 decreases. As a result, the communications module 60 is kept from transmitting an unexpected signal. That is, because the solar cell-attached electronic equipment 100 is supposed to transmit a predetermined signal at a previously expected position in an expected orientation, the above feature can reduce the risk that the solar cell-attached electronic equipment 100 inadvertently transmits the predetermined signal at an unexpected position in an unexpected orientation. Consequently, the feature can reduce the risk that a personal digital assistance held by, for example, a pedestrian identifies a wrong current location.

Furthermore, when the solar cell-attached electronic equipment 100 is mounted on a wall, for example, the outer edge 10X is formed to have an inclination. Such a feature can reduce the risk that the front cover 10 of the solar cell-attached electronic equipment 100 snags clothes, a bag, and another object of a pedestrian, inadvertently breaking the solar cell-attached electronic equipment 100, the clothes, the bag, and the object of the pedestrian.

Returning to FIGS. 18 and 19, the front cover 10 includes a screw boss 10B formed toward the printed wiring circuit board 30; that is, on the rear of the front cover 10. As illustrated in FIG. 15, with the dye-sensitized solar cell 20 and the printed wiring circuit board 30 stacked on the front cover 10, an assembly worker fastens the printed wiring circuit board 30 to the screw boss 10B with a screw to assemble the solar cell-attached electronic equipment 100. In the above manner, the printed wiring circuit board 30 is attached to the front cover 10. While the printed wiring circuit board 30 is attached to the front cover 10, the outer peripheral edge of the printed wiring circuit board 30 and an inner side face of the outer peripheral edge of the cover are kept from touching each other.

In particular, as illustrated in FIG. 15 in this embodiment, the printed wiring circuit board 30 is shaped into a substantial rectangle when viewed from the front. Then, a notch 30Z is formed on each of the longitudinally opposing sides of the printed wiring circuit board 30. As illustrated in FIGS. 15 and 19, a protrusion 10Z is provided to stand on the rear face of the front cover 10. The protrusion 10Z is positioned in association with the notch 30Z.

Moreover, the front cover 10 is also tapered along the opening 10Y for the light-receiving face of the dye-sensitized solar cell 20. Such a feature can also reduce the risk that the front cover 10 of the solar cell-attached electronic equipment 100 snags clothes, a bag, and another object of a pedestrian, inadvertently breaking the solar cell-attached electronic equipment 100, the clothes, the bag, and the object of the pedestrian.

As illustrated in FIGS. 19 and 21, in the solar cell-attached electronic equipment 100 according to this embodiment, the rear cover 40 is attached in further back of the printed wiring circuit board 30. As illustrated in FIG. 19, an outer periphery of the rear cover 40; that is, a peripheral side face of the rear cover 40 is covered with the peripheral edge of the front cover 10.

### Second Embodiment

In the above embodiment, as illustrated in FIG. 17, the dye-sensitized solar cell 20 and the charge element 52 are attached to the front of the printed wiring circuit board 30, and the inspection pads 51a and 51b are attached to the rear of the printed wiring circuit board 30. However, the arrangement of the components shall not be limited to the above arrangement as long as the voltage of the charge element 52 is easily measured while the dye-sensitized solar cell 20 is attached to the front cover 10.

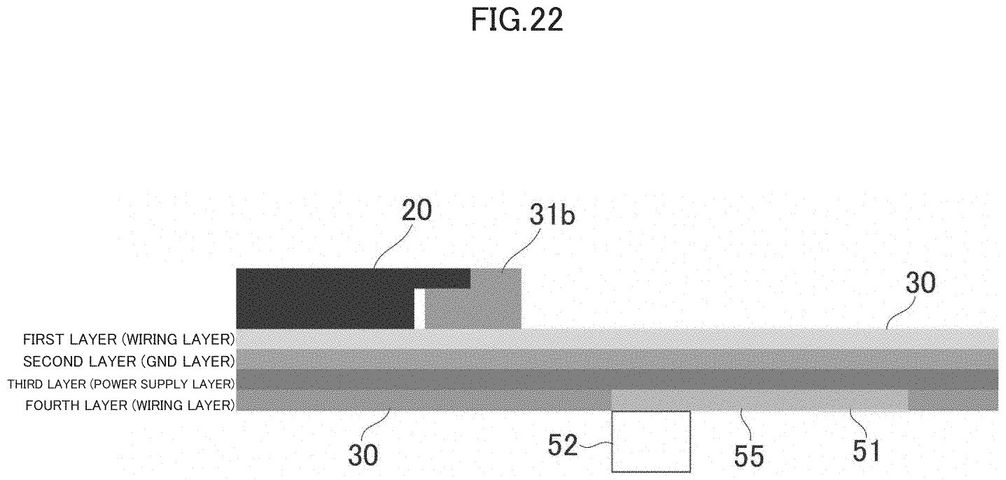

For example, as illustrated in FIG. 22, the dye-sensitized solar cell 20 may be attached to the front of the printed wiring circuit board 30, and the charge element 52 and the inspection pads 51a and 51b may be attached to the rear of the printed wiring circuit board 30.

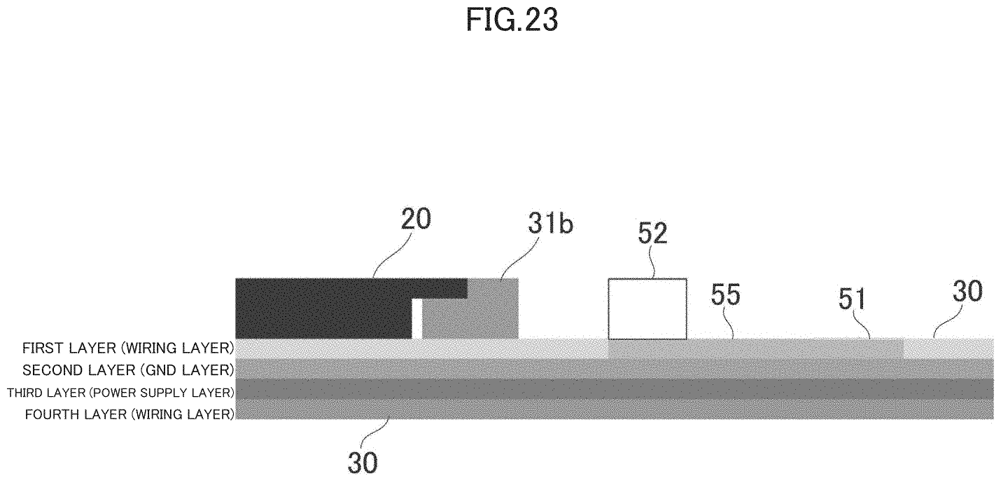

Alternatively, as illustrated in FIG. 23, the dye-sensitized solar cell 20, the charge element 52, and the inspection pads 51a and 51b may be attached to the front of the printed wiring circuit board 30.

### Third Embodiment

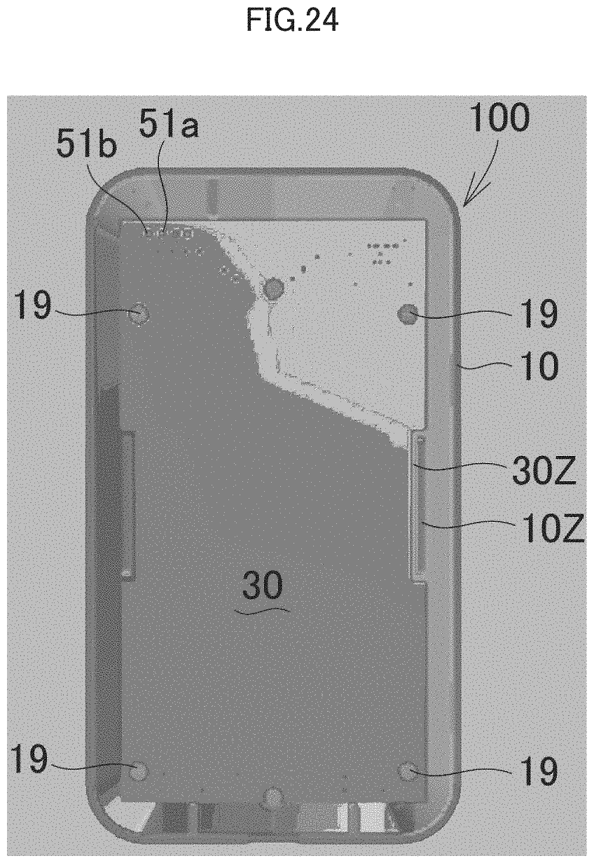

As to the rear cover 40, as illustrated in FIG. 24, the solar cell-attached electronic equipment 100 may be attached to, for example, a wall without the rear cover 40. Alternatively, the rear cover 40 may be attached to the wall in advance, and, after that, the solar cell-attached electronic equipment 100 illustrated in FIG. 24 may be attached to the rear cover 40.

The embodiments disclosed herewith are examples in all respects, and shall not be interpreted to be limitative. The scope of the present invention is intended to be determined not in the above embodiments, but in the claims. All the modifications equivalent to the features of, and within the scope of, the claims are to be included within the scope of the present invention.

### REFERENCE SIGNS LIST

10: Front Cover
10B: Screw Boss
10X: Outer Edge
10Y: Opening
10Z: Protrusion
11: Cushion Material
20: Dye-Sensitized Solar Cell
21: Light-Transparent Substrate
21a: Positive Electrode
21b: Negative Electrode
22: First Light-Transparent Substrate
23a: Light-Transparent Conductive Layer
23b: Light-Transparent Conductive Layer
24: Porous Semiconductor Layer
25: Porous Insulating Layer
26: Counter Electrode Conductive Layer
27: Counter Substrate
28: Sealing Layer
30: Printed Wiring Circuit Board
30Z: Notch
31: Conductive Cushion Material
31a: Conductive Cushion Material
31b: Conductive Cushion Material
32: Double-Sided Adhesive Tape
32a: Land
40: Rear Cover
50: Space
51a: First Inspection Pad
51b: Second Inspection Pad
52: Charge Element
53: Hysteresis Switch
60: Communications Module
100: Solar Cell-Attached Electronic Equipment
311: Conductive Cloth
312: Elastic Material
P: Pressure
W1: Width of Conductive Cushion Material
W2: Width of Electrode
θ: Inclination

1. Solar cell-attached electronic equipment, comprising:
a board including a wire and a land;
a conductive cushion material disposed on the board; and
a solar cell disposed to face the board,
the solar cell including an electrode disposed to face the land, and
the land and the electrode being electrically connected together through the conductive cushion material.

2. The solar cell-attached electronic equipment according to claim 1, further comprising
a cover, wherein
the cover and the board sandwich an edge of the solar cell and the conductive cushion material.

3. The solar cell-attached electronic equipment according to claim 1, wherein
the solar cell includes:
a light-transparent substrate having a light receiving face; and
a light-transparent conductive layer provided on a face, of the light-transparent substrate, across from the light receiving face, wherein
the light-transparent conductive layer has a portion serving as the electrode of the solar cell and facing the land, and
the conductive cushion material is sandwiched between the land and the portion of the light-transparent conductive layer.

4. The solar cell-attached electronic equipment according to claim 1, wherein
the conductive cushion material is fastened to the land with a conductive adhesive tape.

5. The solar cell-attached electronic equipment according to claim 2, wherein
the cover is provided with a cushion material to press the edge of the solar cell toward the board.

6. The solar cell-attached electronic equipment according to claim 3, wherein
the electrode of the solar cell includes:
a first electrode that is a portion of the light-transparent conductive layer located near a longitudinal end of the light-transparent substrate; and
a second electrode that is a portion of the light-transparent conductive layer located near an other longitudinal end of the light-transparent substrate, the second electrode being an opposite electrode to the first electrode.

7. The solar cell-attached electronic equipment according to claim 6, wherein
the first electrode and the second electrode are both provided to the light-transparent substrate toward the board.

8. The solar cell-attached electronic equipment according to claim 6, wherein
the conductive cushion material includes at least two or more conductive cushion materials arranged along the longitudinal end of the light-transparent substrate, and
the conductive cushion material includes at least two or more conductive cushion materials arranged along the other longitudinal end of the light-transparent substrate.

9. The solar cell-attached electronic equipment according to claim 6, wherein
the conductive cushion material is placed more outwards with respect to the light-transparent substrate than the first electrode is.

10. The solar cell-attached electronic equipment according to claim 6, wherein
the light-transparent substrate is pressed against the conductive cushion material so that an upper end of an outward portion of the conductive cushion material is raised above a position at which an inward portion of the conductive cushion material and the light-transparent substrate come into contact.
